(19) United States
(12) Patent Application Publication
(10) Pub. No.: US 2009/0315103 A1
(43) Pub. Date: Dec. 24, 2009

(54) TRENCH MOSFET WITH SHALLOW TRENCH FOR GATE CHARGE REDUCTION

(75) Inventor: Fu-Yuan Hsieh, HsinChu (TW)

Correspondence Address: BAYSHORE PATENT GROUP, LLC, 520 CHANTECLER DR., FREMONT, CA, 94539, US

(73) Assignee: FORCE MOS TECHNOLOGY CO. LTD., HsinChu (TW)

(21) Appl. No.: 12/143,714

(22) Filed: Jun. 20, 2008

(51) Int. Cl. H01L 29/78

(52) U.S. Cl. 257/330; 257/E29.255

(57) ABSTRACT

A power MOS device includes shallow trench structure for reduction of gate charge. To counteract the increase of Rds may caused by decreasing the depth of trench, the power MOS device further includes an arsenic Ion Implantation area underneath each trench bottom when N+ red phosphorus substrate is applied, and the concentration of said arsenic doped area is higher than that of epitaxial layer. As the shallow trench is performed, the gate contact trench could be easily etched over to penetrate the gate oxide, which will lead to a shortage of tungsten plug filled in gate contact trench to epitaixial layer. To prevent from this problem, a terrace poly gate is designed in a preferred embodiment of present invention. By using this method, the gate contact trench is lifted to avoid the shortage problem.

### FIELD OF THE INVENTION

This invention relates generally to the cell design and fabrication process of trench MOSFET devices. More particularly, this invention relates to a novel and improved cell structure and improved process of fabricating a trenched semiconductor power device with reduced drain-source resistance and reduced gate charge, as well as reduced cost.

### BACKGROUND

Conventional technology of forming trenched gate in the power MOS element is encountering a technical difficulty of high gate charge. Only shallow the trench depth may lead to a increase of Rds while the conventional rectangular trench bottom may further decrease breakdown voltage as the electrical field density is high around rectangular trench bottom. On the other hand, when etching the gate contact trench during fabricating process, it is possible to over etched to penetrate through the gate oxide and result in a shortage of tungsten plug filled in the gate contact trench to the epitaxial layer.

In U.S. Pat. No. 6,462,376, a vertical MOSFET element was disclosed, as shown in FIG. 1. A power MOS element is grown on a highly doped n-substrate 40, onto which a layer 42 which is lowly doped with n dopant is implemented to form the drift region. Next to the drift region, a p-doped channel region 44 is formed, and then a strongly n-doped layer 46 is produced on the top surface of the substrate to serve as the source region of the power MOS element. Trenches 124 are provided penetrating through the source region, the channel region and the drift region. A gate oxide 130 lines the sidewalls of the trenches 124. And the trenches 124 are filled with doped polysilicon 152 as shown in FIG. 1. Connecting trenches 134 are etched through the insulator layer 150 to play the role of source contact trench, channel contact trench and gate contact trench, respectively, and then these connecting trenches 134 are filled with tungsten to act as the connecting metal. At the bottom of each connecting trench, a contact hole implantation 135 is carried out, which will help to form a low-resistance contact between source region 46 and the channel region 44. Then a layer of Al alloys 160 is deposited on the top surface of the wafer, and the left portion of the layer, as shown in FIG. 1, is used to apply the same potential to the source region and the channel region, while the right portion 160′ is used to serve as the gate metal.

There are some constrains with the element shown in the mentioned patent. One problem is that, for the purpose of reducing the gate charge, the trench is not etched to a deep depth, and the difference between trench depth and P− body depth is therefore not large, which will parasitically increase Rds according to FIG. 2. In FIG. 2, there are two curves, the upper one represents no As I/I at the bottom of trench, and the lower one represents there is an n-dopant doped area at the bottom of trench, and the difference between the two curves will be discussed below. On the other hand, the shape of the trench, as shown in FIG. 1, is rectangular, which has a larger curvature at the bottom of the trench and will lead to a reduction of BV.

FIG. 3, The upper curve indicates the condition with field plate structure, while the lower one represents the condition with no field plate structure.

Another constraint is that, during the fabricating process, the gate contact trench is etched through an insulating layer and extending into trench filled material, since the distance left is so small and there is no any buffer layer, it could happen that the gate contact trench is over etched through gate oxide and lead to a shortage of tungsten plug filled in the gate contact trench and epitaxial layer.

Accordingly, it would be desirable to provide a power MOS element having lower gate charge, lower Rds and higher BV, and, at the same time, having the probability to prevent the problem of tungsten plug shortage to epitaxial through gate oxide.

### SUMMARY OF THE INVENTION

It is therefore an object of the present invention to provide new and improved power MOS element and manufacture process with reduced gate charge using the shallow trench structure.

Another aspect of the present invention is that, in conventional condition, the using of shallow trench will lead to the increase of Rds, as Rds is dependent on the difference between trench depth and P-body depth, but in accordance with the present invention, this problem could be solved by forming an n dopant implantation area at the bottom of the trench, as shown in FIG. 4, the area 100 is implanted with As, and its concentration is heavier than it of epitaxial layer, as illustrated in FIG. 5, the dashed line indicates the concentration of epitaxial layer, and it can be easily seen that the concentration of the N* area is heavier than that of the epitaxial layer. Refer to FIG. 2 again, the lower curve means the Rds is reduced when using the N* area at the bottom of the trench.

Another aspect of the present invention is that, the bottom of the trench is designed to be arc instead of rectangular, by using of this method, the density of electrical field around the bottom of the trench is lower than the prior art, as the art bottom reduces the curvature. And the most important is the breakdown voltage will not be decreased due to strong electrical field. Another advantage of using the arc bottom is that, when connecting trench is etched, it is easy to penetrate into the epitaxial layer through gate oxide when rectangular bottom is applied, which will lead to the shortage of tungsten plug to epitaxial layer, which means the design of arc trench bottom can partly avoid the chance of shortage. And in another embodiment, this problem could be prevented by forming a terrace poly, as will be discussed below.

Another aspect of the present invention is that, to further reduce Rds, red phosphorus is used in n substrate, for the red phosphorus has lower resistivity (<1.5 micro ohm-cm) than arsenic (<3.0 micro ohm-cm).

Briefly, in a preferred embodiment, the present invention disclosed a power MOS element comprising: an n+ substrate doped with red phosphorus; a drift region with a doping of a first doping type; a P-body region of a second doping type; a source region of strongly n doped formed at the top surface of the substrate; a drain region doped with a first doping type deposited on the rear side of the substrate; a plurality of gate trenches with arc bottom is etched through said source region, said P-body region, and said drift region. Around the bottom of each trench, an n* region doped with a concentration heavier than that of epitaxial layer is formed to further reduce Rds. To fill the trench, the trench-filling material could be doped poly, or combination of doped poly and non-doped poly, and if only doped poly is used, it is necessary to form a silicide on top poly as alternative for lowing gate resistance. Connecting trenches are etched through an insulating layer, said source region and said P-body region as source contact trench, body contact trench and gate contact trench, respectively, and then filled with tungsten as plugs. Said source region and said P-body region are connected to source metal via said source contact trench and said body contact trench, respectively, and said trench gate is connected to gate metal via said gate contact trench. And it should be noticed that, the gate metal deposited dose not serve as field plate as the prior art. In accordance with the present invention, the power device further includes trench floating rings as termination.

In another preferred embodiment, the present invention disclosed a power MOS element with an terrace poly gate comprising: an n+ substrate doped with red phosphorus; a drift region with a doping of a first doping type; a P-body region of a second doping type; a source region of strongly n doped formed at the top surface of the substrate; a drain region doped with a first doping type deposited on the rear side of the substrate; a plurality of gate trenches with arc bottom is etched through said source region, said P-body region, and said drift region. And what should be noticed is that, the trench gates for gate metal contact are designed to be wider than those in active area. Around the bottom of each trench, an n* region doped with a concentration heavier than that of epitaxial layer is formed to further reduce Rds. To fill the trench, the trench-filling material could be doped poly, or combination of doped poly and non-doped poly, and if only doped poly is used, it is necessary to form a silicide on top poly as alternative for lowing gate resistance. In accordance with the present invention of this embodiment, it is necessary to apply additional mask for gate formation, and the width of poly remained for gate metal contact is not greater than trench gate width to further improve gate oxide integrity, because of no overlap between terrace gate and top trench corner due to thinner gate oxide around trench corner. Said source region and said P-body region are connected to source metal via a source contact trench and a body contact trench, respectively, said trench gate is connected to gate metal via a gate contact trench, and all said contact trench are filled with tungsten plugs. In accordance with the present invention, the power device further includes trench floating rings as termination.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of a power MOS element of prior art;

FIG. 2 is a profile showing the dependence of Rds on difference between trench depth and P-body depth;

FIG. 3 is a profile showing the dependence of breakdown voltage on P-body junction depth while considering the resistance of epitaxial layer is 0.4 ohm-cm;

FIG. 4 is a cross-section of a small portion of a power MOS element of the present invention;

FIG. 5 is a profile illustrating the doping concentration distributed along channel region from silicon surface;

FIG. 6 is a cross-section of a power MOS element of the first embodiment for the present invention;

FIG. 7 is a cross-section of a power MOS element of another embodiment for the present invention;

FIG. 8A to 8D are a serial of side cross sectional views for showing the processing steps for fabricating a power MOS element as shown in FIG. 6;

FIG. 9A to FIG. 9B are a serial of side cross sectional views for showing the processing steps for fabricating a power MOS element as shown in FIG. 7.

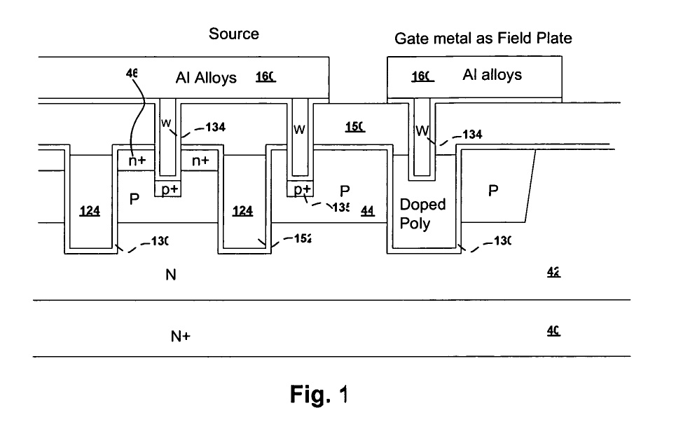

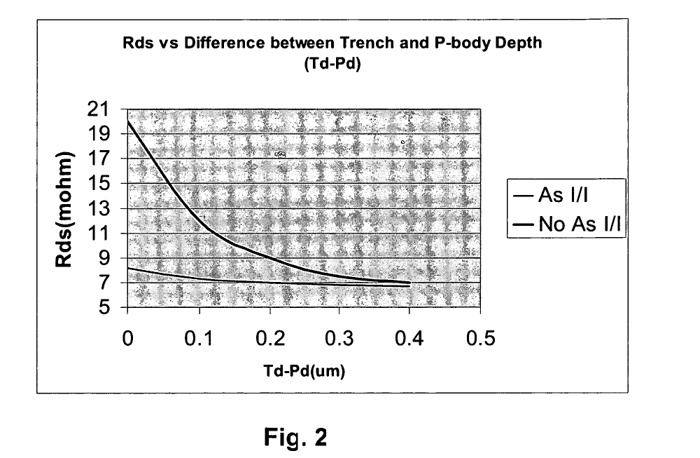

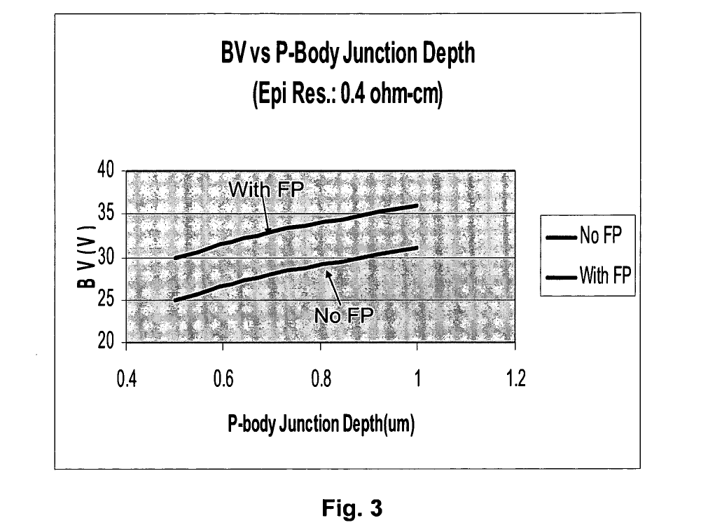

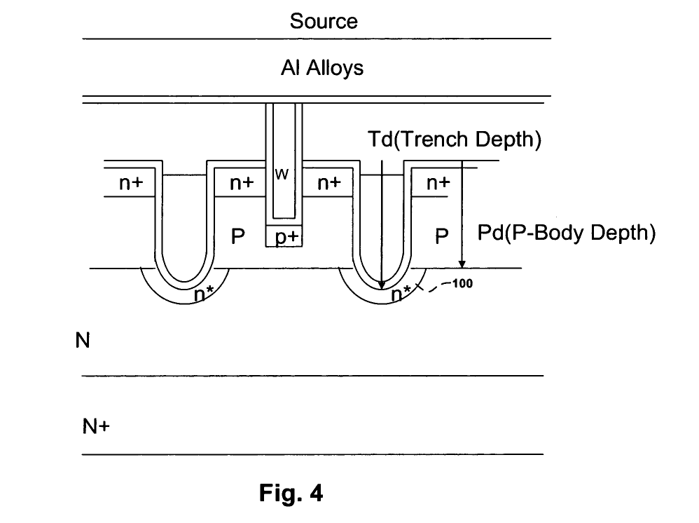

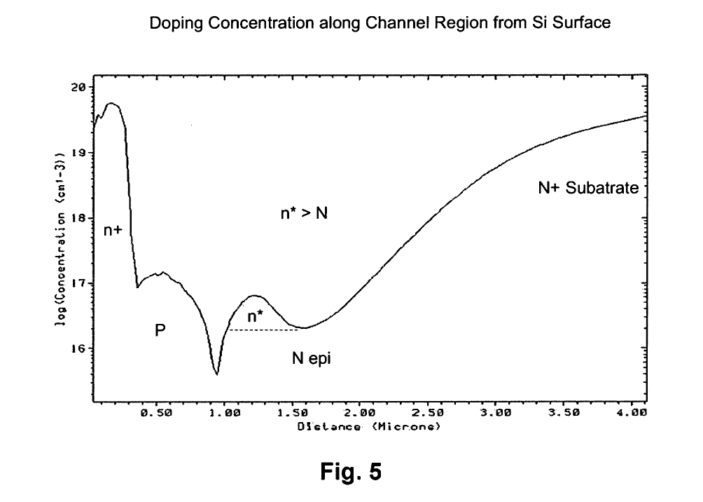

### DETAILED DESCRIPTION OF THE EMBODIMENTS

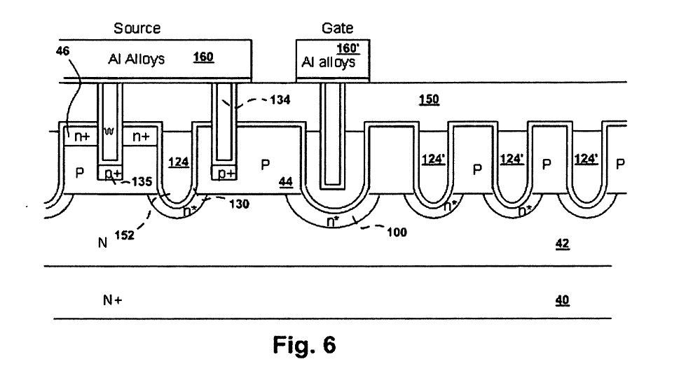

Please refer to FIG. 6 for an preferred embodiment of this invention where a power MOS element is formed on a red phosphorus N+ substrate 40, onto which formed an N epitaxial layer 42. The power MOS element further includes a trenched gate 124 disposed in a trench 124 with a gate insulation layer 130 formed over the walls of the trench. A body region 44 that is doped with a dopant of second conductivity type, e.g., P-type dopant, extends between the trenched gates. Trenches 124′ serves as floating trench rings as termination, and among all trenches, the trench for gate metal contact is wider than other else. It should be noticed that, the bottom of each trench, as shown in FIG. 6, is designed to be arc to form shallow trench for further reducing gate charge. Around said trench bottom, an N* region 100 is formed by arsenic Ion Implantation to further reduce Rds caused by decreasing the trench depth. Source region 46 doped with a first doping type is formed on the top surface of the substrate. Connecting trenches are produced through insulating layer 150, said source region 46 and into said body region 44, at the bottom of each connecting trench, a contact hole implantation 135 is carried out, which will help to form a low-resistance contact between source region 46 and the channel region 44. Tungsten plugs 134 act as the connecting metal to connect said source region, said body region and said trench gate to source metal and gate metal, respectively. As illustrated in FIG. 6, gate metal does not serve as field plate as prior art.

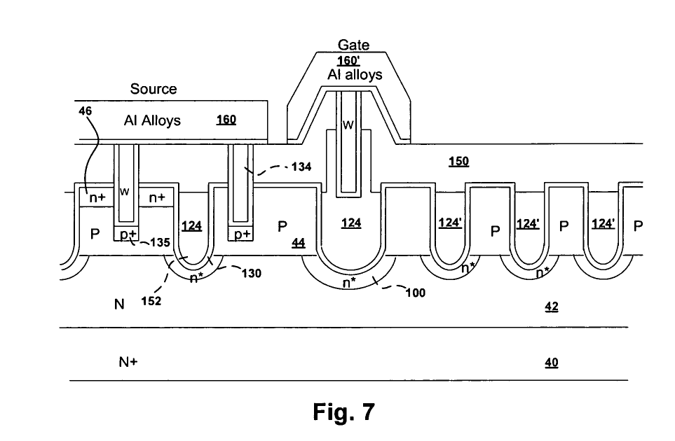

For the purpose of avoiding the connecting trench penetrating through oxide layer and resulting in shortage of tungsten plug to epitaxial layer, a terrace poly gate is designed, as shown in FIG. 7. Additional poly mask is needed here to form terrace poly gate above wide trench, which can effectively lift the gate contact trench to a higher place to avoid the tungsten plug penetrating through oxide layer.

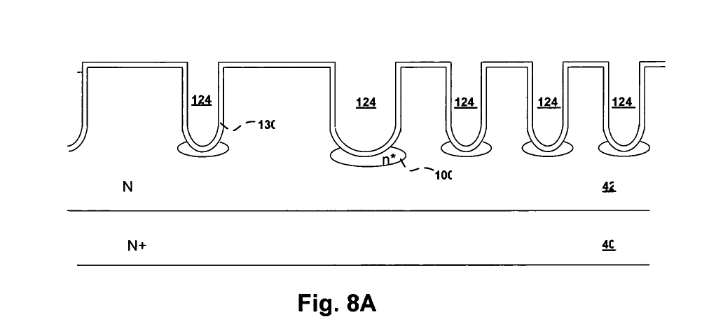

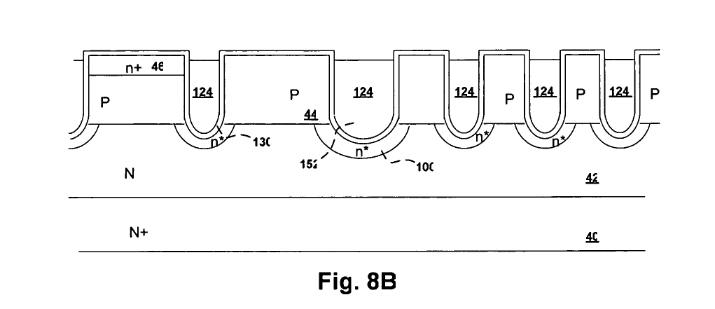

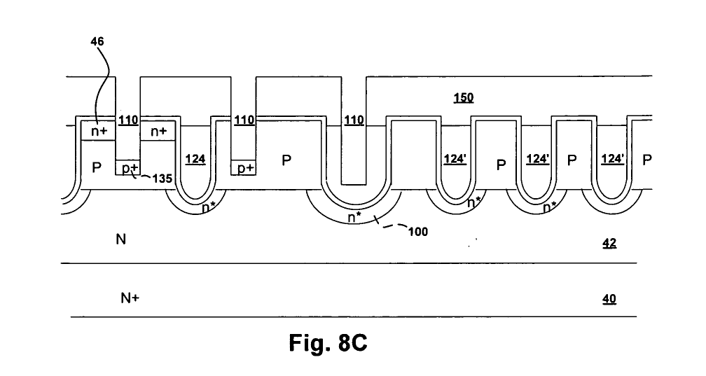

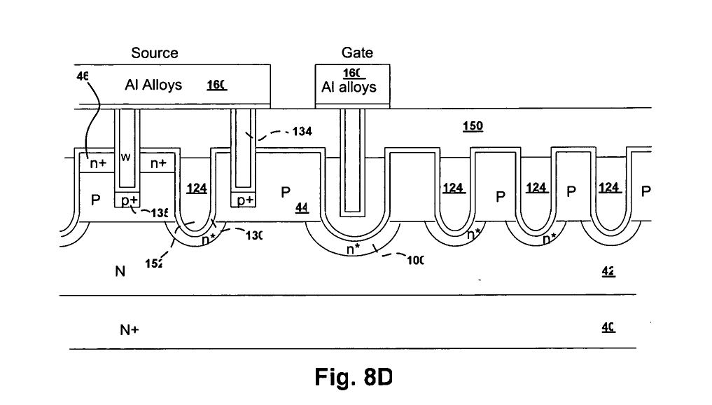

FIGS. 8A to 8D show a series of exemplary steps that are performed to form the inventive power MOS element. In FIG. 8A, an N− doped epitaxial layer 42 is grown on a N+ substrate 40 doped with red phosphorus. A trench mask is formed by covering the surface of epitaxial layer 42 with an oxide layer, which is then conventionally exposed and patterned to leave mask portions. The patterned mask portions define the trenches 124 and floating trench rings 124′. Trench 124 and 124′ are dry Si etched through the mask opening to a certain depth, then, the mask portion is removed. After the removal, a step of arsenic Ion Implantation is performed for N* 100 formation around each bottom of trench 124 and 124′ for further reducing Rds. And a gate oxide layer 130 is deposited on the entire structure of the element. Next, all trenches are filled with doped poly or combination of doped poly and non-doped poly 152. Then, the filling-in material 152 is etched back to expose the potion of the gate oxide layer 130 that extends over the surface of P-body 44. For further reducing gate resistance, a layer of silicide is formed on top of poly (not shown) as alternative. After that, followed by a step of P-body Ion Implantation, and then the diffusion step for P-body drive-in. The second mask is then applied to form source region 46, followed by an N dopant Ion Implantation and diffusion step for source region drive-in.

In FIG. 8C, the process continues with the deposition of oxide layer 150 over entire structure. A contact mask is applied to carry out a contact etch to open the contact opening 110 by applying a dry oxide etch through the oxide layer 150 and followed by a dry silicon etch to open the contact openings 110 further deeper into the source region 46 and the P-body region 44. A BF 2 Ion Implantation process is followed for the formation of contact hole 135 for further reducing the resistance between source region 46 and P-body region 44.

In FIG. 8D, Ti/TiN is filled into the trenched contact openings. Then the contact plugs composed of tungsten are filled into the trenched contact openings. The contact plugs 13 are formed to contact the source region 46, the P-body region 44 and trench gate, respectively. Then, a tungsten etch back and Ti/TiN etch back is performed followed by a metal layer formation. A metal mask is applied to pattern the metal layer into a source metal 160 and a gate metal layer 160′. The source metal 160 is in electrical contact with the trenched source contact plug and P-body contact plug, while the gate metal 160′ is in electrical contact with the trenched gate contact.

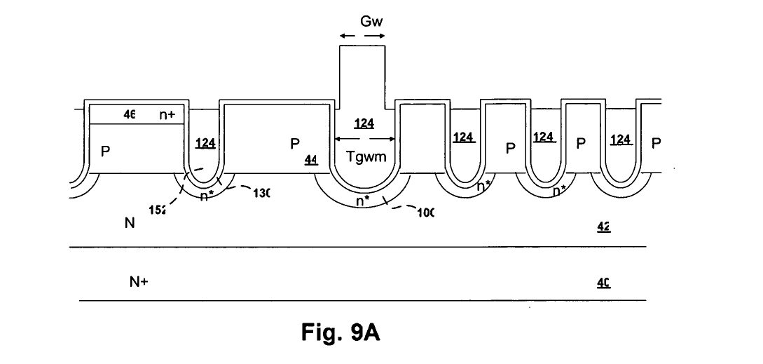

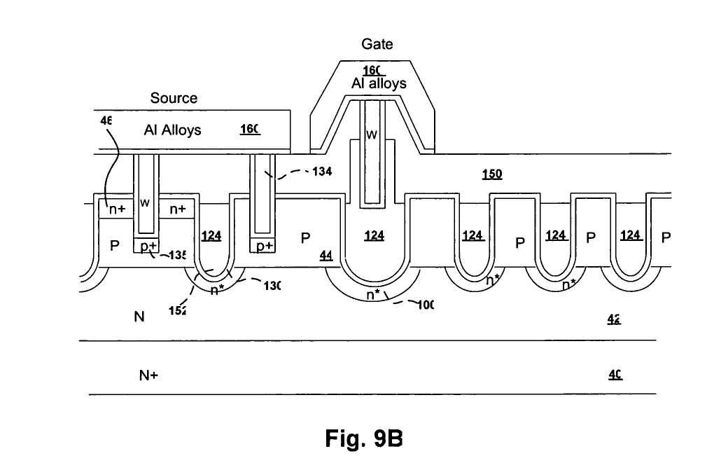

FIGS. 9A to 9B are a series of exemplary steps that are performed to form the inventive power MOS element of another preferred embodiment. In FIG. 9A, the former steps are the same as the first embodiment as shown in FIG. 8A and FIG. 8B. As illustrated in FIG. 9A, Tgwm represents the width of the wider trench for gate contact, while Gw indicates the gate width, e.g., the portion of poly remained for gate metal contact. Gw is designed to smaller than Tgwm to improve gate oxide integrity, as no overlap between terrace gate and top trench corner due to thinner gate oxide around trench corner. In FIG. 9B, before the deposition of Al alloys, an additional mask is needed to form a terrace poly gate. With this method, the contact trench for gate contact is lifted to prevent the shortage of tungsten plug to epitaxial layer.

The masks used in the two preferred embodiment mentioned above is different. In the first preferred embodiment, four masks is needed during entire process, while in the second preferred embodiment, an additional terrace poly mask is applied to implement the function of avoiding shortage problem, that is to say, five masks is needed in the second preferred embodiment.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A vertical semiconductor power MOS device comprising a plurality of semiconductor power cells with each cell comprising a trenched gate surrounded by a source region encompassed in a body region above a drain region disposed on a bottom surface of a substrate, wherein said MOS cell further comprising:
a substrate;
a heavily doped area with the same doping type as epitaxial layer underneath said trench bottom to further reduce Rds;
a source-body contact trench opened through an insulating layer covering said cell structure and extending into said source region and said body region;
a gate contact trench opened through said insulating layer and extending into trench-filling material in said trenched gate underneath gate runner metal;
a plurality of floating trench rings as termination;
a source metal layer formed on a top surface of the MOSFET;
a gate metal layer formed on a top surface of the MOSFET; and
a drain metal layer formed on a bottom surface of the MOSFET.

2. The MOSFET of claim 1, wherein the concentration of said heavily doped region is higher than the concentration of epitaxial layer.

3. The MOSFET of claim 1 wherein said trench gate for gate metal contact is wider than those in active area.

4. The MOSFET of claim 1 wherein said trench-filling material is doped poly.

5. The MOSFET of claim 1 wherein said trench-filling material is combination of doped poly and non-doped poly.

6. The MOSFET of claim 1 wherein said trench-filling material is doped poly with silicide on the poly top.

7. The MOSFET of claim 4 wherein the top level of said doped poly in said gate contact trench is same as that in said trench gates in active area.

8. The MOSFET of claim 4 wherein the top level of said doped poly in said gate contact trench is higher than that in said trench gates in active area, formed by adding additional gate mask.

9. The MOSFET of claim 6 wherein said gate mask is not greater than said gate contact trench for gate metal runner connection.
